(19) United States
(12) Patent Application Publication
(10) Pub. No.: US 2025/0063705 A1
(43) Pub. Date: Feb. 20, 2025

(54) COOLING DEVICE

(71) Applicant: Magna Powertrain GmbH & Co KG, Lannach (AT)

(72) Inventors: Werner Ness, Manhartsbrunn (AT); Helmuth Sachsenmaier, Graz (AT)

(21) Appl. No.: 18/720,903

(22) PCT Filed: Nov. 16, 2022
(86) PCT No.: PCT/EP2022/082116

§ 371 Date: Jun. 17, 2024

(30) Foreign Application Priority Data
Dec. 21, 2021 (DE) 10 2021 214 756.9

(51) Int. Cl. H05K 7/20

(52) U.S. Cl. CPC H05K 7/20927; H05K 7/20272

(57) ABSTRACT

A cooling device for cooling a power module has cooling channels between a base and a cover of the cooling device. A cooling medium can flow in the cooling channels. The base and/or the cover is in the form of a metal surface for thermal connection to the power module. Side walls of the cooling channels are formed by ribs. At predefined positions, the ribs have local deflections from the usual course of the cooling channel in question so that a turbulent flow of the cooling medium occurs locally at each deflection.

### CROSS-REFERENCE TO RELATED APPLICATIONS

This application is a National Stage of International Application No. PCT/EP2022/082116, filed Nov. 16, 2022, which claims priority to DE 10 2021 214 756.9 filed Dec. 21, 2021. The entire disclosures of each of the above applications are incorporated herein by reference.

### FIELD

The present disclosure relates to a cooling device for cooling a power module of an inverter and to a method for producing a cooling device of this kind.

### BACKGROUND

This section provides information related to the present disclosure which is not necessarily prior art.

It is already known that power modules, that is to say power switches in inverters, can be cooled by way of a cooling liquid. In this context, a distinction can be drawn between direct and indirect cooling and metallically attached power modules.

The cooling effect of the known cooling structures is usually distributed uniformly over a total cooling surface of a cooling module. The cooling capacity is generally distributed between a plurality of cooling modules in such a way that the last module in a series receives the warmest cooling medium and thus has the lowest capacity.

The known cooling structures are usually produced by way of complex production methods such as forging and extrusion and generally also require finishing.

### SUMMARY

This section provides a general summary of the disclosure, and is not a comprehensive disclosure of its full scope or all of its features.

It is an object of the present disclosure to provide a cooling device for cooling a power module, which allows improved distribution of the cooling capacity and, at the same time, is also simple to produce. It is also an object of the present disclosure to provide a simple method for producing a cooling device of this kind.

The object is achieved by a cooling device for cooling a power module, wherein the cooling device has cooling channels between a base and a cover of the cooling device, wherein a cooling medium can flow in the cooling channels, wherein the base and/or the cover are/is designed as a metallic surface for thermal connection to the power module, wherein side walls of the cooling channels are formed by ribs, wherein the ribs have, at predefined positions, local deflections from the usual course of the cooling channel in question, with the result that turbulent flow of the cooling medium occurs locally at the respective deflection.

According to the present disclosure, a cooling device has cooling channels through which a cooling medium flows during operation. Local deflections are provided in these cooling channels, with the result that the cooling medium is deflected locally from the usual course of the cooling channel, and turbulent flow of the cooling medium occurs locally at the respective deflection.

It is thereby possible to achieve cooling with pinpoint accuracy, in particular at a location of high heat generation (hot spot).

The cooling device can be, for example, a cooling module that can interact with other cooling modules of the same type.

The cooling device can be formed by a two-part cooling channel, in particular by an extruded profile having cooling ribs and by a cover. Cooling with pinpoint accuracy can be achieved by the installation of the local deflections, i.e. of swirl elements (turbolizers).

Further developments of the present disclosure are given throughout the present disclosure, the description, and the accompanying drawings.

The cooling device preferably has at least two, preferably many, substantially parallel cooling channels, wherein each rib has, at predefined positions, local deflections from the usual course of the cooling channel in question, with the result that turbulent flow of the cooling medium occurs locally at the respective deflection.

The local deflections of adjacent ribs are preferably arranged offset with respect to one another in the direction of the usual course of the cooling channel in question, that is to say along the cooling channels.

The local deflections of each nth rib are preferably once again in the same position in the direction of the usual course of the cooling channel in question. Here, n can be, in particular, three, with the result that the “axial” positions of the deflections (along the cooling channel) are repeated at each third rib.

The local deflections are preferably formed by parts of the ribs which are set obliquely to the usual course of the respective cooling channel. In particular, the local deflections can be flat surfaces which are arranged obliquely to the usual course of the rib. The oblique surfaces can each be formed by an additional component but are preferably formed integrally with the ribs themselves, by forming.

The formation of the obliquely set parts of the ribs is preferably performed by mechanical working, in particular deformation, of the ribs, in particular of the profile. As a preferred option, therefore, no additional construction elements are required for the formation of the deflection structures.

The ribs are preferably formed on the base of the cooling device, in particular integrally with the base.

The base with the ribs is preferably formed by an extruded profile, in particular from a corrosion-resistant material.

The cover is preferably mounted on the base and/or the ribs, in particular being welded to the base and/or the ribs in order to withstand the pressure in the interior of the cooling device.

The cooling device preferably has two connections for the entry and exit of the cooling medium into/from the cooling channels. The connections can be connected in a fluid-tight manner to a higher-level device, in particular to a component of an inverter, in particular to an inverter housing.

The object is also achieved by a method for producing a cooling device as indicated above, wherein the base with the ribs is produced as an extruded profile, wherein local deflections from the usual course of the cooling channel in question are then introduced at predefined positions into the ribs.

Local deflections from the usual course of the cooling channel in question are introduced at predefined positions into the ribs, preferably by forming parts of the ribs at the predefined positions.

The cover is preferably welded to the base and/or the ribs after the local deflections have been introduced, in particular after the partial forming of the ribs.

Further areas of applicability will become apparent from the description provided here-in. The description and specific examples in this summary are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

FIG. 1 is a schematic sectional view of a cooling device according to the present disclosure from the side.

FIG. 2 is a schematic sectional view of a cooling device according to the present disclosure according to section A-A in FIG. 1, from above.

### DETAILED DESCRIPTION

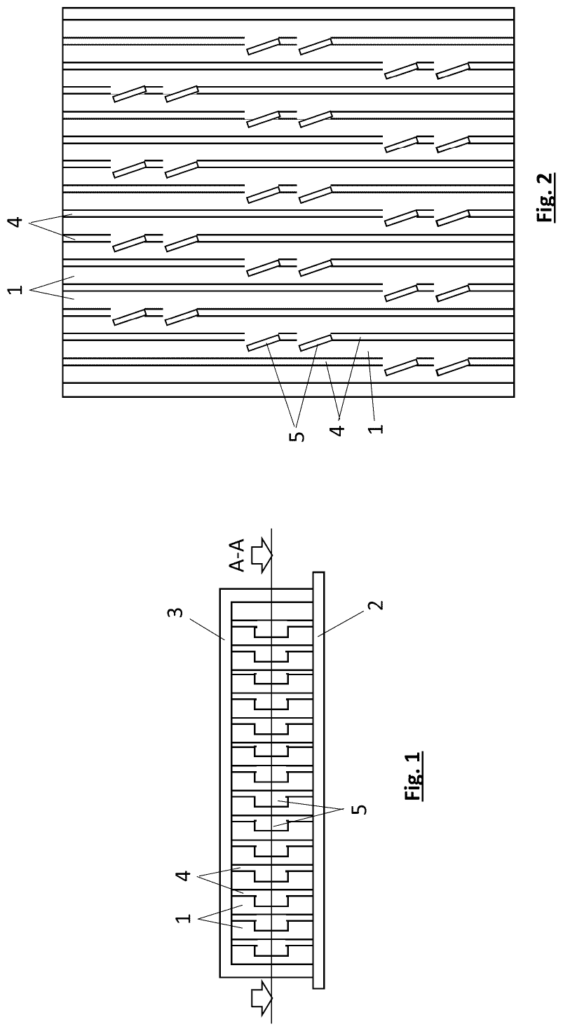

FIGS. 1 and 2 schematically show a cooling device according to the present disclosure from the side and from above.

The cooling device serves to cool a power module of an inverter and has a plurality of mutually parallel cooling channels 1, through which a cooling medium, or coolant, can flow. The cooling channels 1 are formed between a base 2 and a cover 3 of the cooling device. The base 2 is formed integrally with ribs 4 by an extruded profile. The cover 3 is mounted on the base 2 and, with the latter, forms a delimited leaktight space for the coolant.

The base 2 and the cover 3 are designed as metallic surfaces for thermal connection to the power module, thus enabling the cooling device to cool on both sides. The surfaces of the base 2 and of the cover 3 are flat and allow the mounting of the power modules, e.g. in a double-sided manner. The surfaces are preferably produced without additional mechanical machining, such as grinding or milling.

The side walls of the cooling channels 1 are formed by the ribs 4, which project vertically upward in an integral manner from the base 2 of the cooling device.

At predefined positions, the ribs 4 have local deflections 5 from the usual course of the cooling channel 1 in question, with the result that turbulent flow of the cooling medium occurs locally at the respective deflection 5.

The local deflections 5 are formed by parts of the ribs 4 which are oblique with respect to the usual course of the respective cooling channel 1, that is to say oblique or diagonal in comparison with the rest of the side walls of the cooling channels.

The local deflections 5 of adjacent ribs 4 are arranged offset with respect to one another in the direction of the usual course of the cooling channel 1 in question, that is to say in the general direction of flow.

The local deflections 5 of each third rib 4 are once again at the same position in the direction of flow.

The local deflections 5 of the cooling device can form a regular pattern or, alternatively, can be distributed in an irregular manner in the cooling device.

A cooling device of this kind can be attached mechanically and thermally by a metallic connecting surface for the cooling of (half-bridge) power modules.

Liquid cooling media such as water or antifreeze mixtures can be used as a cooling medium, for example.

The deflection structures in the extruded profile are configured to achieve turbulent flow at defined local positions in order to reduce the thermal resistance there.

The deflection structures 5 in the extruded profile are produced by mechanical working of the profile. There are no additional component elements in the system, such as deflection grids or additional plates.

The production of the deflection structures 5 in the cooling ribbing 4 can be performed by way of a press/stamping tool in a single-stage operation.

### LIST OF REFERENCE SIGNS

1 cooling channels
2 base
3 cover
4 rib
5 local deflection

What is claimed is:

1. A cooling device for cooling a power module, comprising:
a base:
a cover:
cooling channels between the base and the cover of the cooling device,
wherein the cooling channels are arranged such that a cooling medium can flow in the cooling channels,
wherein the base and/or the cover are/is a metallic surface for thermal connection to the power module,
wherein side walls of the cooling channels are formed by ribs and define a usual course of each of the cooling channels,
wherein the cooling channels and ribs extend in a first direction:
wherein the ribs have, at predefined positions, local deflections, wherein the local deflections deflect from the usual course of the cooling channel in question, such that turbulent flow of the cooling medium occurs locally at the respective local deflection.

2. The cooling device as claimed in claim 1, wherein the cooling device has at least two, substantially parallel cooling channels, wherein each rib has, at predefined positions, the local deflections-from the usual course of the cooling channel in question, such that turbulent flow of the cooling medium occurs locally at the respective deflection.

3. The cooling device as claimed in claim 2, wherein the local deflections of adjacent ribs are arranged offset with respect to one another in the direction of the usual course of the cooling channel in question.

4. The cooling device as claimed in claim 3, wherein the local deflections of each nth rib are in the same position in the direction of the usual course of the cooling channel in question, wherein n is greater than two.

5. The cooling device as claimed in claim 1,
wherein the local deflections are formed by parts of the ribs which are set obliquely to the usual course of the respective cooling channel.

6. The cooling device as claimed in claim 1,
wherein the ribs are formed on the base of the cooling device.

7. The cooling device as claimed in claim 6,
wherein the base with the ribs is formed by an extruded profile.

8. The cooling device as claimed in claim 1,
wherein the cover is mounted on the base and/or on the ribs.

9. The cooling device as claimed in claim 1,
wherein the cooling device has two connections for entry and exit of the cooling medium into/from the cooling channels.

10. A method for producing a cooling device as claimed in claim 1, wherein the base and the ribs is are produced as an extruded profile, wherein the local deflections from the usual course of the cooling channel in question are then introduced into the ribs at the predefined positions.

11. The method as claimed in claim 10, wherein the local deflections from the usual course of the cooling channel in question are introduced into the ribs-by forming parts of the ribs at the predefined positions.

12. The method as claimed in claim 10, wherein the cover-is welded to the base and/or the ribs after the local deflections have been introduced.

13. The cooling device as claimed in claim 1, wherein each rib having the local deflections includes a pair of local deflections.

14. The cooling device as claimed in claim 1, wherein the cooling channels and the ribs extend in a longitudinal direction, and the ribs are arranged laterally adjacent, wherein the local deflections for a given rib are offset in the longitudinal direction relative to each laterally adjacent rib.

15. The cooling device as claimed in claim 4, wherein the local deflections of each third rib are at the same position in the direction of the usual course of the cooling channel in question.

16. The cooling device as claimed in claim 6, wherein the ribs are formed integrally with the base.

17. The cooling device as claimed in claim 7, wherein the ribs are formed integrally with the base, wherein the base with the ribs is formed from a corrosion resistant material.

18. The cooling device as claimed in claim 8, wherein the cover is welded to the base.

19. The cooling device as claimed in claim 1, wherein the local deflections are produced by mechanical working of the ribs, wherein there are no additional deflection grids or additional plates in the profile of the cooling channels.
